(19) United States
(12) Patent Application Publication
(10) Pub. No.: US 2009/0014839 A1
(43) Pub. Date: Jan. 15, 2009

(54) Nitride-Based Semiconductor Device

(75) Inventors: Masayuki Sonobe, Kyoto (JP); Norikazu Ito, Kyoto (JP); Kazuaki Tsutsumi, Kyoto (JP); Tetsuya Fujiwara, Kyoto (JP)

Correspondence Address: RABIN & Berdo, PC, 1101 14TH STREET, NW, SUITE 500, WASHINGTON, DC, 20005, US

(73) Assignee: ROHM CO., LTD, KYOTO (JP)

(21) Appl. No.: 12/223,785

(22) PCT Filed: Feb. 8, 2007
(86) PCT No.: PCT/JP2007/052266

§ 371 Date: Aug. 8, 2008

(30) Foreign Application Priority Data
Feb. 9, 2006 (JP) 2006-032917

(51) Int. Cl. H01L 29/20

(52) U.S. Cl. 257/615; 257/E29.089

(57) ABSTRACT

A nitride-based semiconductor device includes: an n-GaN layer 103; an active layer 104 formed on the n-GaN layer 103; a first AlGaN layer 105 formed on the active layer 104 at a growth temperature ranging from 900 to 1200° C. and by doping of Mg at a doping concentration ranging from 5×10¹⁹ to 2×10²⁰/cm³; a second AlGaN layer 106 formed on the first AlGaN layer 105 at a growth temperature ranging from 900 to 1200° C.; and a p-GaN layer 107 formed on the second AlGaN layer 106.

### TECHNICAL FIELD

The present invention relates to a nitride-based semiconductor device.

### BACKGROUND ART

A gallium nitride semiconductor light-emitting device serves as a semiconductor light-emitting device, such as a light-emitting diode, a semiconductor laser device, and the like, which emits a light ranging from ultraviolet to green or a white light. In a manufacture of a GaN-based semiconductor device, it is difficult to manufacture a substrate made of GaN; thus, a GaN-based semiconductor layer is epitaxially grown on a substrate made of sapphire, SiC, or Si, or the like.

For example, as shown in FIG. 3, a GaN low-temperature buffer layer 202, an n-GaN layer 203, an InGaN multiple quantum well (MQW) active layer 204, and the like are sequentially formed on a (0001) surface of a sapphire substrate 201 by an MOCVD (Metal Organic Chemical Vapor Deposition) method. Further, a p-GaN layer 207 and the like are sequentially formed on the active layer 204.

However, in some cases in the structure illustrated in FIG. 3, an impurity such as Mg, which is included as a dopant in the p-GaN layer 207, diffuses into the active layer 204, and, as a result, the active layer 204 is deteriorated.

In order to prevent such diffusion of the impurity, a structure is disclosed in which a p-AlGaN layer is formed between an active layer and a p-GaN layer at a growth temperature equivalent to that of the active layer (for example, refer to Japanese Patent Application Publication No. 2000-208814). To be more specific, as illustrated in FIG. 4, a GaN low-temperature buffer layer 302, an n-GaN layer 303, an InGaN multiple quantum well (MQW) active layer 304, and the like are sequentially formed on the (0001) surface of a sapphire substrate 301 by the MOCVD method. Further, a p-AlGaN layer 308 is formed on the active layer 304 at a low temperature, and a p-GaN layer 307 and the like are sequentially formed on the p-AlGaN layer 308.

### DISCLOSURE OF THE INVENTION

However, in the structure illustrated in FIG. 4, the p-AlGaN layer 308 is formed at a low temperature. Accordingly, there is a problem that crystallization is poor and thus a p-type conversion is difficult to achieve.

Therefore, in view of the above-described problem, the present invention aims to provide a nitride-based semiconductor device in which the crystallization is improved without impurity such as Mg diffusing into an active layer.

In order to achieve the above object, the present invention is summarized as a nitride-based semiconductor device, including (a) a nitride-based semiconductor layer formed on a substrate and includes at least one layer; (b) an active layer formed on the nitride-based semiconductor layer; (c) a first AlGaN layer formed at a growth temperature ranging from 900 to 1200° C. and by a doping of Mg at a doping concentration ranging from 5×10¹⁹ to 2×10²⁰/cm³; and (d) a second AlGaN layer formed on the first AlGaN layer and formed at a growth temperature ranging from 900 to 1200° C.

In the nitride-based semiconductor device according to the present invention, it is possible to form the second AlGaN layer by a growth at an optimal concentration, by having the first AlGaN layer serving as a protection film of the active layer. Accordingly, crystallization of the nitride-based semiconductor layer can be improved without impurity such as Mg diffusing into the active layer.

In addition, it is preferable that a thickness of the first AlGaN layer be ranging from 5 to 10 nm in the nitride-based semiconductor device according to the present invention.

### BRIEF DESCRIPTION OF THE DRAWINGS

FIG. 1 is a cross-sectional view of the nitride-based semiconductor device according to an embodiment of the present invention.

FIG. 2 is a cross-sectional view for describing a producing method of the nitride-based semiconductor device according to the embodiment of the present invention.

FIG. 3 is a cross-sectional view of a conventional nitride-based semiconductor device (version 1).

FIG. 4 is a cross-sectional view of a conventional nitride-based semiconductor device (version 2).

### BEST MODE FOR CARRYING OUT THE INVENTION

Next, by referring to the drawings, an embodiment of the present invention will be described. In the descriptions of the drawings, same or similar parts are denoted by same or similar reference numerals. However, it should be noted that the drawings are merely schematic representations, and individual measurements, ratios, and the like are different from actual ones. Therefore, concrete measurements and the like should be determined in consideration of the descriptions to be given below. In addition, it is obvious that there may be differences in relations in measurements and ratios among drawings.

### (Nitride-Based Light-Emitting Diode Device)

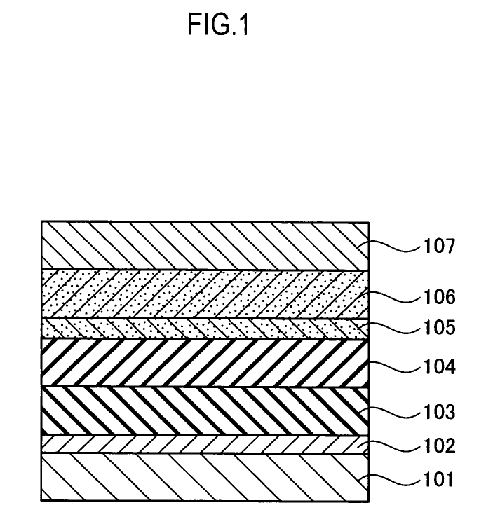

FIG. 1 is a cross-sectional view of a nitride-based light-emitting diode device according to the embodiment of the present invention. In the nitride-based light-emitting diode device, as illustrated in FIG. 1, a GaN low-temperature buffer layer 102 is formed on a sapphire substrate 101, an n-type GaN layer 103 is formed on the GaN low-temperature buffer layer 102, an active layer 104 having a multiple quantum well (MQW) structure is formed on the n-type GaN layer 103, a first AlGaN layer 105 is formed on the active layer 104, a second AlGaN layer 106 is formed on the first AlGaN layer 105, and a p-type GaN layer 107 is formed on the second AlGaN layer 106.

As described above, in the nitride-based light-emitting diode device according to the embodiment of the present invention, the AlGaN layers, which are located immediately above the active layer 104, form a bilayer structure. The first AlGaN layer 105 located closer to the active layer 104 has a high doping concentration of Mg, and is formed by a growth at a high temperature. In the meantime, the second AlGaN layer 106 located closer to the p-type semiconductor layer 107 is formed by a growth at a high temperature so that crystallization of AlGaN itself can be improved.

To be more specific, the first AlGaN layer 105 is formed at a growth temperature ranging from 900 to 1200° C. (for example, 1010° C.) and by a doping of Mg at a doping concentration ranging from 5×10¹⁹ to 2×10²⁰°/cm³.

Meanwhile, the second AlGaN layer 106 is formed at a growth temperature ranging from 900 to 1200° C. (for example, 1060° C.) and by a doping of Mg at a doping concentration ranging from 2 to 4×10¹⁹/cm³.

### (Manufacture Method of Nitride-Based Light-Emitting Diode Device)

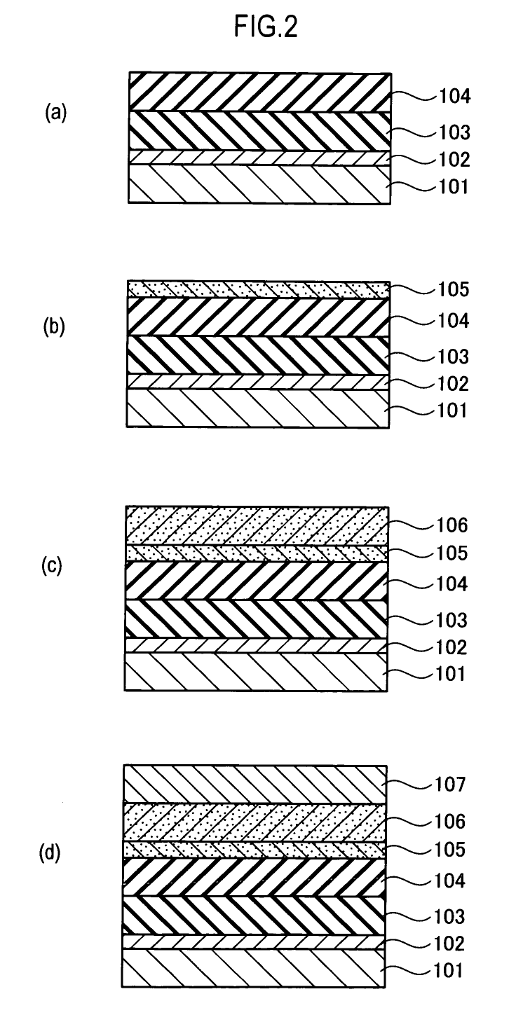

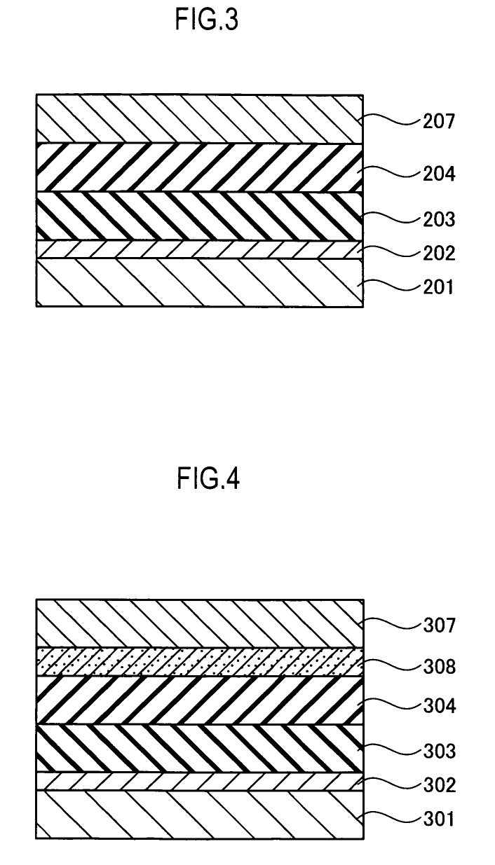

Next, a description will be given of a manufacture method of the nitride-based light-emitting diode device according to the present embodiment. FIG. 2 is a cross-sectional view for describing the manufacture method of the nitride-based light-emitting diode device according to the embodiment of the present invention.

First, as illustrated in FIG. 2(a), a low-temperature GaN buffer layer 102 is formed on a sapphire substrate 101 by the MOCVD (Metal Organic Chemical Vapor Deposition) method.

For example, in a state where the sapphire substrate 101 is maintained at a temperature of approximately ranging from 400 to 700° C., a buffer layer made of undoped non-single crystal GaN is formed on the (0001) surface of the sapphire substrate 101 by using a raw material gas composed of NH₃ and TMG (trimethyl gallium).

Next, an n-type GaN layer 103 is formed on the low-temperature GaN buffer layer 102.

For example, in a state where the sapphire substrate 101 is maintained at a growth temperature of approximately ranging from 900 to 1200° C. (for example, 1050° C.), a base layer made of undoped single crystal GaN is formed on the buffer layer by using a raw material gas composed of NH₃ and TMG.

Next, in a state where the sapphire substrate 101 is maintained at a growth temperature of approximately ranging from 900 to 1200° C. (for example, 1050° C.), an n-type contact layer made of Si-doped single crystal GaN is formed on the base layer by using a raw material gas composed of NH₃ and TMG, and a dopant gas composed of SiH₄.

As described above, the n-type GaN layer 103 is made of the base layer, the n-type contact layer, and the like. In addition, for example, a thickness of the n-type GaN layer 103 is approximately ranging from 4 to 6 μm.

Next, in a state where the sapphire substrate 101 is maintained at a growth temperature of approximately ranging from 700 to 800° C. (for example, 760° C.), an active layer 104 made of undoped single-crystal InGaN is formed on the n-type GaN layer 103 by using a raw material gas composed of NH₃, TMG, or TMI (trimethyl indium) while introducing a carrier gas composed of N₂. The active layer 104 has an MQW structure in which a well layer and a barrier layer are formed to grow alternately. For example, five layers of the well layer and six layers of the barrier layer are alternately formed to grow. In addition, for example, the thickness of the active layer 104 is approximately 0.1 μm.

Next, as shown in FIG. 2(b), in a state where the sapphire substrate 101 is maintained at a growth temperature of approximately ranging from 900 to 1200° C. (for example, 1010° C.), a first AlGaN layer 105 made of Mg-doped single-crystal AlGaN is formed on the active layer 104 by using a carrier gas composed of H₂ and N₂, a raw material gas composed of NH₃, TMG, and TMA, and a dopant gas composed of CP₂Mg. At this time, the doping concentration of Mg is as high as ranging from 5×10¹⁹ to 2×10²⁰/cm³. In addition, for example, an Al composition of the first AlGaN layer 105 is ranging from 5 to 15%, and a thickness of the first AlGaN layer 105 is approximately 5 nm.

Next, as shown in FIG. 2(c), in a state where the sapphire substrate 101 is maintained at a growth temperature of approximately ranging from 900 to 1200° C. (for example, 1060° C.), a second AlGaN layer 106 made of Mg-doped single-crystal AlGaN is formed on the first AlGaN layer 105 by using a carrier gas composed of H₂ and N₂, a raw material gas composed of NH₃, TMG, and TMA, and a dopant gas composed of CP₂Mg. At this time, the doping concentration of Mg is ranging from 2 to 4×10¹⁹/cm³, which is a low concentration compared to that of the first AlGaN layer 105. Furthermore, the growth temperature of the second AlGaN layer 106 is higher than that of the first AlGaN layer 105. In addition, for example, an Al composition of the second AlGaN layer 106 is ranging from 5 to 15%, and a thickness of the second AlGaN layer 106 is approximately 15 nm.

Next, as shown in FIG. 2(d), in a state where the sapphire substrate 101 is maintained at a growth temperature of approximately ranging from 900 to 1200° C. (for example, 1010° C.), a p-type GaN layer 107 is formed on the second AlGaN layer 106 by using a carrier gas composed of H₂ and N₂, a raw material gas composed of NH₃ and TMG, and a dopant gas composed of CP₂Mg. In addition, for example, a thickness of the p-type GaN layer 107 is approximately ranging from 0.05 to 0.2 μm.

Thereafter, for example, a p-type electrode made of Ag, Pt, Au, Pd, Ni, ZnO, and the like are sequentially formed by a vacuum deposition method, a sputtering method, and the like.

### (Operation and Effect)

In the nitride-based semiconductor device according to the present embodiment, the AlGaN layers, which are located immediately above the active layer 104, form a bilayer structure. Further, the first AlGaN layer 105 located closer to the active layer 104 is formed by the growth at the high doping concentration and at the higher growth temperature than the doping concentration of the active layer 104. In the nitride-based semiconductor device according to the present embodiment, it is possible to form the second AlGaN layer by the growth at the optimal concentration, by having the first AlGaN layer serving as a protection film of the active layer 104. Accordingly, the crystallization of the second AlGaN layer 106 and the p-type GaN layer 107 can be improved without impurity such as Mg diffusing into the active layer 104.

Furthermore, since the doping concentration of Mg in the first AlGaN layer 105 is high, the number of holes is increased; therefore, a light-emitting efficiency can be improved. In this regard, the first AlGaN layer 105 is formed at a high temperature, since more defects can exist if the first AlGaN layer 105 is formed at a low temperature.

Moreover, in order to prevent an evaporation of In and the like caused by the growth of the first AlGaN layer 105 at a high temperature, the first AlGaN layer 105 is required to be formed thinly in a short period of time. For this reason, it is preferable that a thickness of the first AlGaN layer 105 be ranging from 5 to 10 nm.

Still furthermore, although containing a large amount of Mg, the first AlGaN layer 105 has a good crystallization because it is formed by a grown at a high temperature. Accordingly, it is unlikely that Mg diffuses into the active layer 104.

### OTHER EMBODIMENTS

The present invention is described by the above embodiment; however, the descriptions and drawings constituting a part of this disclosure should not be understood to limit this invention. This disclosure will reveal various alternative embodiments, examples, and applications to those skilled in the art.

For example, in the embodiment of the present invention, the manufacture method of the light-emitting diode using a light emitted from the active layer in the nitride-based semiconductor device layer has mainly been described as an example. Not being limited to this, the present invention is applicable to a manufacture of a light-emitting device in which a semiconductor laser and a fluorescent material using an emitted light from these light-emitting devices as an excitation light are combined. Moreover, the present invention is also applicable to an electronic device, such as an HEMT (High Electron Mobility Transistor) having a nitride-based semiconductor device layer, an SAW (Surface Acoustic Wave) device, and a light-receiving element.

Furthermore, in the embodiment of the present invention, it is described that each nitride semiconductor layers is formed by a crystal growth, by using the MOCVD method. However, the present invention is not limited to this, and each nitride-based semiconductor layers may be formed by the crystal growth, by using an HVPE method, a gas source MBE method, and the like. Moreover, the crystal structure of the nitride-based compound semiconductor may be a wurtzite-type or a sphalerite-type structure. In addition, a plane direction of the growth is not limited to (0001), and may be (11-20) or (1-100).

Moreover, in the embodiment of the present invention, the nitride-based semiconductor device layer including layers made of GaN, AlGaN, InGaN, AlN, and the like is employed. However the present invention is not limited to this, and a nitride-based semiconductor device layer including layers other than a layer made of GaN, AlGaN, InGaN, and AlN may be employed. In addition, the shape of the semiconductor device layer may include a current confinement structure, such as a mesa structure and a ridge structure.

Furthermore, in the embodiment of the present invention, a sapphire substrate is employed as a substrate for the growth of the nitride-based semiconductor device layer. However, the present invention is not limited to this, and any substrate on which a nitride-based semiconductor can be grown, for example, Si, SiC, GaAs, MgO, ZnO, spinelle, and GaN can be employed.

Still furthermore, in the embodiment of the present invention, the active layer and the p-type semiconductor layer are stacked on the n-type semiconductor layer. However, the active layer and the n-type semiconductor layer may be stacked on the p-type semiconductor layer.

As described above, it is obvious that the present invention includes various embodiments and the like which are not described here. Thus, the technical scope of the present invention is only defined by the claimed elements of the invention according to the appropriate scope of the claims on the basis of the above descriptions.

### INDUSTRIAL APPLICABILITY

According to the present invention, it is possible to provide a nitride-based semiconductor device in which crystallization is improved without an impurity such as Mg diffusing into an active layer.

1. A nitride-based semiconductor device, comprising:
a nitride-based semiconductor layer formed on a substrate and includes at least one layer;
an active layer formed on the nitride-based semiconductor layer;
a first AlGaN layer formed at a growth temperature ranging from 900 to 1200° C. and by a doping of Mg at a doping concentration ranging from 5×10¹⁹ to 2×10²⁰/cm³; and
a second AlGaN layer formed on the first AlGaN layer and formed at a growth temperature ranging from 900 to 1200° C.

2. The nitride-based semiconductor device according to claim 1, wherein a thickness of the first AlGaN layer is ranging from 5 to 10 nm.
